(19) United States
(12) Patent Application Publication
(10) Pub. No.: US 2011/0170710 A1
(43) Pub. Date: Jul. 14, 2011

(54) METHOD AND APPARATUS FOR ADJUSTING VOLUME

(75) Inventor: Beak-kwon SON, Suwon-si (KR)

(73) Assignee: SAMSUNG ELECTRONICS CO., LTD., Suwon-si (KR)

(21) Appl. No.: 12/907,075

(22) Filed: Oct. 19, 2010

(30) Foreign Application Priority Data
Jan. 12, 2010 (KR) 10-2010-0002748

(51) Int. Cl. H03G 5/00

(52) U.S. Cl. 381/98

(57) ABSTRACT

A method of adjusting volume removes an audio signal of a first frequency band from audio signals, and increases the volume of the audio signal from which the signal of the first frequency band is removed.

### CROSS-REFERENCE TO RELATED PATENT APPLICATION

This application claims the benefit of Korean Patent Application No. 10-2010-0002748, filed on Jan. 12, 2010, in the Korean Intellectual Property Office, the disclosure of which is incorporated herein in its entirety by reference.

### BACKGROUND

1. Field

The exemplary embodiments relate to a method and apparatus for adjusting volume, and more particularly, to a method and apparatus for adjusting volume, which increase the volume of an audio signal by removing a signal of a certain frequency band from the audio signal.

2. Description of the Related Art

In order to prevent a speaker from being damaged, an audio signal should be reproduced to be equal to or less than a rated output power of the speaker. However, when the audio signal is reproduced to a level equal to or less than the rated output power of the speaker, volume of the reproduced audio signal is reduced. That is, there is a trade-off between the volume of the audio signal and the rated output power of the speaker.

When an audio signal of excessively large volume is reproduced, a stress ratio is adjusted by reducing a gain at a reproducing end in order to reproduce the audio signal under the rated output power of the speaker. When an audio signal of general volume that has already been stored in a memory is reproduced in a state where the gain of the reproducing end is set to be low, the volume of the audio signal decreases.

In addition, when an input signal is recorded to generate an audio signal and the audio signal is reproduced where the gain at the reproducing end is set to be low, volume of the reproduced audio signal is decreased due to the low gain. Therefore, in order to reproduce the recorded audio signal above a certain reference volume, a gain at a recording end should be set to be high when recording the input signal. However, when the gain at the recording end is set to be high, a sound source of the recorded audio signal is saturated, and thereby degrading sound quality.

FIG. 1 is a graph showing a wavelength of volume of an audio signal that is recorded where a gain at a recording end is set to be high. In FIG. 1, a horizontal axis denotes time, and a vertical axis denotes volume of the audio signal. Referring to FIG. 1, when the gain at the recording end is set to be high, some part of the volume of an input signal that is to be recorded exceeds a maximum recordable level. Audio signals exceeding the maximum recordable level are saturated to the maximum recordable level, in order to be recorded. The recorded sound source after being saturated becomes a cause of degrading the sound quality such as clipping when reproducing the audio signals.

### SUMMARY

The exemplary embodiments provide a method and apparatus for adjusting volume in order to allow an audio signal to be reproduced with volume and sound quality above a reference level under a rated output power of a speaker.

According to an aspect of an exemplary embodiment, there is provided a method of adjusting volume, the method including: removing an audio signal of a first frequency band from the audio signal; and increasing the volume of the audio signal from which in which the audio signal of the first frequency band is removed.

The method may further include generating the audio signal by recording an input signal, and the generating of the audio signal may include adjusting a recording gain so as not to saturate the audio signal.

The first frequency band may be included in a frequency band of an audio signal that is not reproducible through a speaker. The first frequency band may be a band of frequency that is equal to or less than 800 Hz. The method may further include receiving a selection of the first frequency band of which the audio signal is removed from a user.

The increasing of the volume of the audio signal may include: calculating an amount of volume of the audio signal that is reduced in a time domain corresponding to the removed signal of the first frequency band; and increasing the volume of the audio signal by using the calculated amount of volume. The method may further include, when a voltage value of the audio signal, the volume of which is increased, is greater than a first voltage value, reducing the volume of the audio signal so that the voltage value of the audio signal is reduced less than the first voltage value.

The reducing of the volume may include: calculating an average voltage value of the audio signal, the volume of which is increased, in a frame unit; and reducing the volume of the audio signal so that the average voltage value of the audio signal greater than the first voltage value is reduced less than the first voltage value. The method may further include: adjusting a gain of the audio signal, the volume of which is adjusted; and outputting the audio signal from which the gain is adjusted. The first voltage value may be smaller than a value of rated output power of the speaker.

The method may further include increasing the first voltage value so as not to exceed the rated output power of the speaker. The adjusting of the first voltage value may include receiving the selection of the first voltage value from the user.

According to another aspect of an exemplary embodiment, there is provided a volume adjusting apparatus including: a low frequency signal deduction unit for removing an audio signal of a first frequency band from audio signal; and a volume amplifier for increasing volume of the audio signal from which in which the audio signal of the first frequency band is removed.

According to another aspect of an exemplary embodiment, there is provided a computer readable recording medium having embodied thereon a program for executing a method of adjusting volume, the method including: removing an audio signal of a first frequency band from audio signals; and increasing the volume of the audio signal from which in which the signal of the first frequency band is removed.

### BRIEF DESCRIPTION OF THE DRAWINGS

The above and other features of the exemplary embodiments will become more apparent by describing in detail with reference to the attached drawings in which:

FIG. 1 is a graph illustrating a wavelength of volume of an audio signal that is recorded where a gain at a recording end is set to be high;

FIG. 2 is a block diagram of an internal structure of a volume adjusting apparatus according to an exemplary embodiment;

FIG. 3 is a block diagram of an internal structure of a volume adjusting apparatus according to another exemplary embodiment;

FIG. 4 is a block diagram of an internal structure of an audio signal processing apparatus according to an exemplary embodiment;

FIG. 5 is a graph showing waveforms of volume of an audio signal that is recorded by an audio signal generator shown in FIG. 4;

FIG. 6 are graphs showing an audio signal from which a signal of a first frequency band is removed by a volume adjusting apparatus according to an exemplary embodiment; and

FIG. 7 is a flowchart illustrating a method of processing an audio signal, according to an exemplary embodiment.

### DETAILED DESCRIPTION

Hereinafter, exemplary embodiments will be described with reference to accompanying drawings.

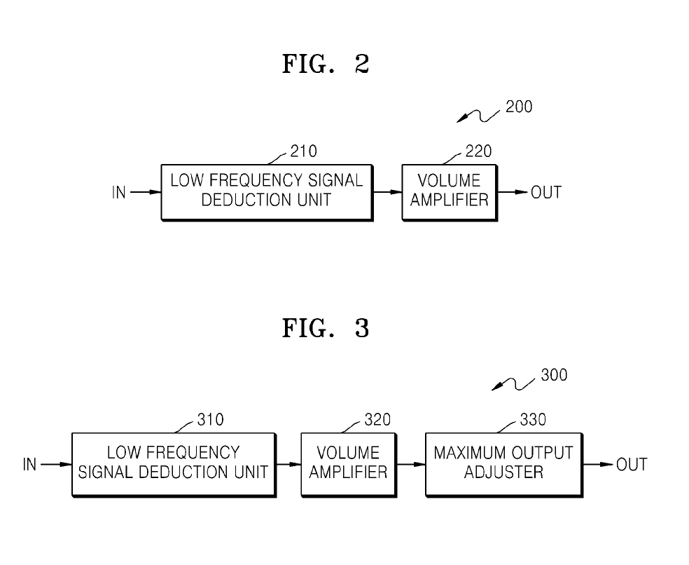

FIG. 2 is a block diagram of an internal structure of a volume adjusting apparatus 200 according to an exemplary embodiment. The volume adjusting apparatus 200 of FIG. 2 includes a low frequency signal deduction unit 210 and a volume amplifier 220. The volume adjusting apparatus 200 may be included in an audio signal processing apparatus (not shown) as a unit, may be separate from an audio signal processing apparatus, or may be used independently from the audio signal processing apparatus.

The low frequency signal deduction unit 210 removes signal of a first frequency band from an audio signal.

The audio signal processing apparatus does not output signal of low frequency bands due to the characteristics of the hardware in the audio signal processing apparatus. Therefore, even when the audio signal of a low frequency band, which is not reproduced by the audio signal processing apparatus, is removed, volume and sound quality of the reproduced audio signal are not changed.

The low frequency signal deduction unit 210 removes the signal of low frequency band, which is not reproduced by the audio signal processing apparatus. For example, the first frequency band may be a frequency band from about 100 Hz to about 800 Hz.

The audio signal may be displayed in a time domain or on a frequency domain. That is, the audio signal may be represented as volume of the audio signal according to frequency or the volume of the audio signal according to time. In the case where the low frequency signal deduction unit 210 removes the audio signal of the first frequency band from the audio signals in the frequency domain, when the audio signal, from which the audio signal of the first frequency band is removed, is represented in the time domain, the volume of the audio signal is less than the original audio signal, from which the audio signal of the first frequency band is not removed. That is, a waveform denoting the volume of the audio signal according to time is reduced.

As described above, since the audio signal processing apparatus cannot reproduce the audio signal of a certain frequency band, the volume output from a speaker (not shown) is constant even when the volume of the audio signal according to time is reduced by the removal of the audio signal of a certain frequency band.

The low frequency signal deduction unit 210 may secure a gain margin, head room for increasing the volume, by removing the signal of the first frequency band from the audio signal. The low frequency signal deduction unit 210 transmits the audio signal from which the signal of the first frequency band is removed, to the volume amplifier 220.

The volume amplifier 220 increases the volume of the audio signal that is transmitted from the low frequency signal deduction unit 210 by applying a gain. Since a gain margin that is applicable is increased due to the removal of the signal of the first frequency band, the volume amplifier 220 may increase the volume higher than that of an original audio signal. The volume amplifier 220 calculates an amount of volume of the audio signal reduced in the time domain corresponding to the removed signal of the first frequency band, and increases the volume of the audio signal by using the amount of reduced volume.

As described above, according to the present exemplary embodiment, the audio signal of the low frequency band, which is not reproduced by the audio signal processing apparatus, is removed, and the volume of the audio signal according to time may be increased by as much as the removed audio signal.

FIG. 3 is a block diagram of an internal structure of a volume adjusting apparatus 300 according to another exemplary embodiment. The volume adjusting apparatus 300 of FIG. 3 includes a low frequency signal deduction unit 310, a volume amplifier 320, and a maximum output adjuster 330. The volume adjusting apparatus 300 of FIG. 3 is different from the volume adjusting apparatus 200 of FIG. 2 in view of the maximum output adjuster 330. The low frequency signal deduction unit 310 and the volume amplifier 320 included in the volume adjusting apparatus 300 of FIG. 3 respectively perform the same functions as those of the low frequency signal deduction unit 210 and the volume amplifier 220 of the volume adjusting apparatus 200 of FIG. 2, and thus, detailed descriptions of thereof are not provided here.

The maximum output adjuster 330 receives the audio signal, the volume of which is increased, from the volume amplifier 320. The maximum output adjuster 330 adjusts the volume of the audio signal transmitted from the volume amplifier 320 again. The maximum output adjuster 330 adjusts an output of the audio signal transmitted from the volume amplifier 320, which exceeds a rated output power. That is, when there is a signal having a voltage value exceeding a certain voltage value among the audio signals transmitted from the volume amplifier 320, the maximum output adjuster 330 adjusts the volume so that the voltage value of that signal is under the certain voltage value.

To this end, the maximum output adjuster 330 calculates a root mean square (RMS) in a frame unit to calculate an average voltage value of the audio signal, and determines whether the average voltage value of the audio signal calculated per a frame unit is greater than a reference threshold value, that is, a first voltage value. When the average voltage value of the audio signal is greater than the first voltage value, the maximum output adjuster 330 adjusts a gain of an audio signal sample in the frame so that the average voltage value of the audio signals included in that frame may be smaller than the first voltage value. The maximum output adjuster 330 adjusts the volume per a frame unit, and thus, the audio signal of low volume in the frame is not changed and the audio signal of high volume in the frame may be adjusted. The maximum output adjuster 330 adjusts the volume in frame unit, and thus, adjusts the volume of the audio signal included in the frame exceeding the first voltage value without changing the audio signal in the frame which is less than the first voltage value.

In the exemplary embodiments, the first voltage value may be equal to or smaller than a rated output power of the speaker. When the first voltage value is smaller than the rated output power of the speaker, the volume adjusting apparatus 300 may adjust the first voltage value as much as possible, provided that the first voltage value does not exceed the rated output power of the speaker. The first voltage value is adjusted as much as possible, because as the first voltage value increases, a signal distortion is reduced.

According to the exemplary embodiments, the volume of the audio signal that exceeds the reference voltage value is decreased, and thus, the voltage value of the audio signal does not exceed the rated output power of the speaker.

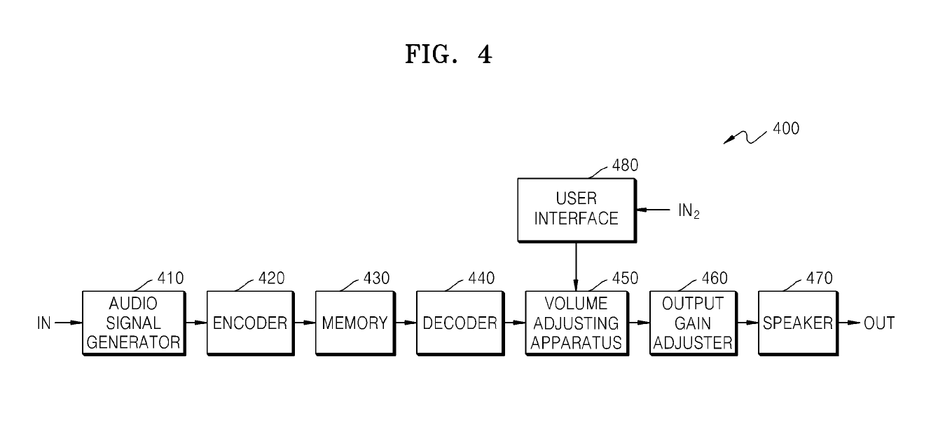

FIG. 4 is a block diagram of an internal structure of an audio signal processing apparatus 400 according to an exemplary embodiment. The audio signal processing apparatus 400 includes an audio signal generator 410, an encoder 420, a memory 430, a decoder 440, a volume adjusting apparatus 450, an output gain adjuster 460, a speaker 470, and a user interface 480.

The audio signal processing apparatus 400 may record an input signal to generate an audio signal, and reproduces the generated audio signal and the audio signal stored in the memory 430. The audio signal processing apparatus 400 may be an MPEG audio layer-3 (MP3) player, a personal media player (PMP), a CD player, a digital versatile disk (DVD) player, or a mobile terminal.

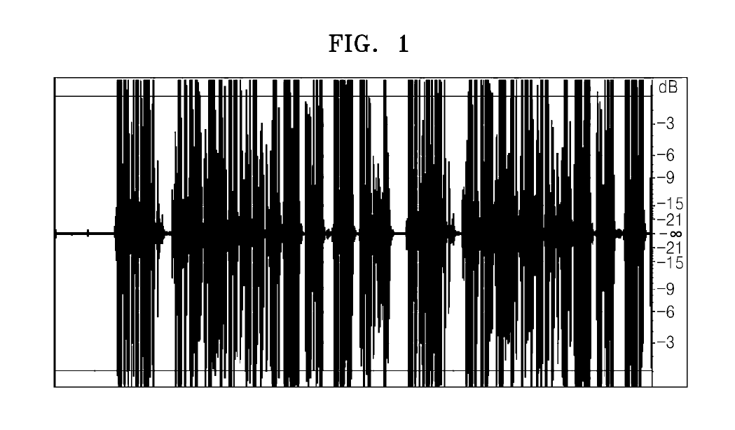

The audio signal generator 410 records an input signal to generate an audio signal. The audio signal generator 410 includes a recording microphone to record the input signal and adjusts a gain of the input signal. As described with reference to FIG. 1, according to the prior art, a recording gain of an audio signal generator may be excessively high in order to increase the volume at an output end and an audio signal may be saturated. However, in the present exemplary embodiment, the volume adjusting apparatus 450 increases the volume of the audio signal, and thus, there is no need to set the recording gain of the audio signal generator 410 to be excessively high. That is, the audio signal generator 410 may set the recording gain within a range in which the recorded signal is not saturated.

The audio signal processor 410 transmits the generated audio signal to the encoder 420.

The encoder 420 encodes the generated audio signal, and transmits the encoded audio signal to the memory 430.

The memory 430 stores the encoded audio signal transmitted from the encoder 420. The audio signal processing apparatus 400 may further include a communication unit (not shown), and in this case, the memory 430 may store an audio signal that is downloaded from an external server via the communication unit. The memory 430 may be built in the audio signal processing apparatus 400, or may be an external memory, for example, a universal serial bus (USB) or a disk such as a DVD or a blue-ray disk (BD), that is detachable from the audio signal processing apparatus 400.

The decoder 440 decodes the audio signal stored in the memory 430, and transmits the decoded audio signal to the volume adjusting apparatus 450.

The volume adjusting apparatus 450 removes the audio signal of the first frequency band from the received audio signal, and increases the volume of the audio signal from which the audio signal of the first frequency band is removed.

The volume adjusting apparatus 450 may receive a user's selection of the frequency band to be removed via the user interface 480. In this case, the volume adjusting apparatus 450 removes the signal of the selected frequency band.

The volume adjusting apparatus 450 increases the volume of the audio signal in the time domain by as much as the audio signal of the first frequency band that is removed.

If necessary, the volume adjusting apparatus 450 may decrease the volume of the audio signal, which has a volume above a certain reference value among the audio signals having increased volume, below the reference value. To do this, the volume adjusting apparatus 450 calculates the voltage value of the audio signal, the volume of which is increased in the frame unit and decreases the volume of the audio signal so that the voltage value of the audio signal greater than the first voltage value in frame unit may be equal to or less than the first voltage value.

The volume adjusting apparatus 450 may receive the user's selection of the first voltage value via the user interface 480. That is, the output voltage of the audio signal may be adjusted according to the user's selection. However, the first voltage value is smaller than a value of the rated output power of the first voltage value.

The output gain adjuster 460 adjusts a gain of the audio signal output from the speaker 470. The output gain adjuster 460 calculates the gain that will be applied to the audio signals so as to output the audio signal with an output voltage less than the rated output power of the speaker, and applies the calculated gain to the audio signal. The output gain adjuster 460 is different from the volume adjusting apparatus 450, which adjusts the volume of the audio signal per the frame unit, in that the output gain adjuster 460 applies the same gain to the entire audio signals.

The speaker 470 outputs the audio signal, the gain of which is adjusted by the output gain adjuster 460.

The user interface 480 receives commands, characters, features, or voice information from the user by using a physical transducer such as a keyboard, a keypad, a mouse, a touch pad, a touch screen, or a microphone, and informs the audio signal processing apparatus 400 about the information. The user interface 480 receives the user's selection about the frequency band that is to be removed from the audio signal, and transfers the received selection to the volume adjusting apparatus 450. In addition, the user interface 480 receives the user's selection of the first voltage value that is the reference value when increasing the volume of audio signal, and transmits the selected first voltage value to the volume adjusting apparatus 450.

As described above, according to the exemplary embodiments, the volume adjusting apparatus 450 adjusts the volume of the audio signal, and then, the audio signal having a volume above the predetermined reference value may be output. In addition, when the input signal is recorded to generate the audio signal, there is no need to use a excessively large recording gain.

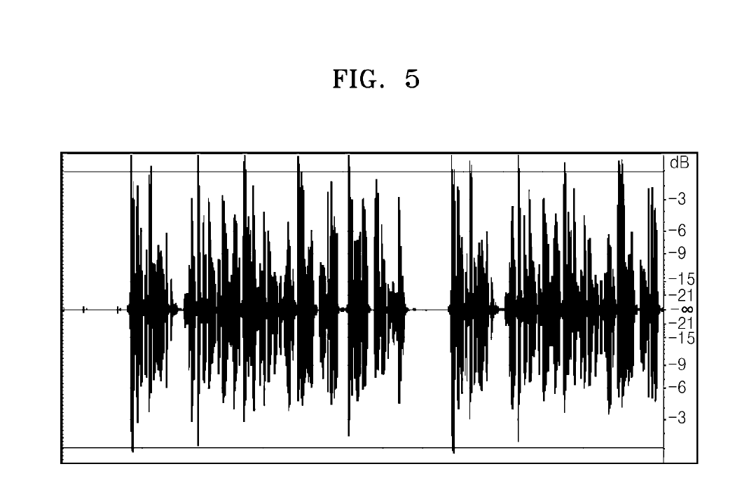

FIG. 5 is a graph showing waveforms of volume of the audio signal recorded by the audio signal generator 410 shown in FIG. 4. The audio signal generator 410 may set the recording gain so that the audio signal is not saturated.

In the graphs of FIG. 5, a horizontal axis denotes time and a vertical axis denotes volume of the audio signal. Unlike FIG. 1, in which the recording signal of high recording gain is shown, FIG. 5 shows that the volume of the recorded input signal is mostly included in the maximum recordable level. Therefore, the sound source saturation that is generated in the audio signals exceeding the maximum recordable level does not occur, and thus, a clipping phenomenon does not occur when reproducing the recorded signal, and thereby improving the sound quality.

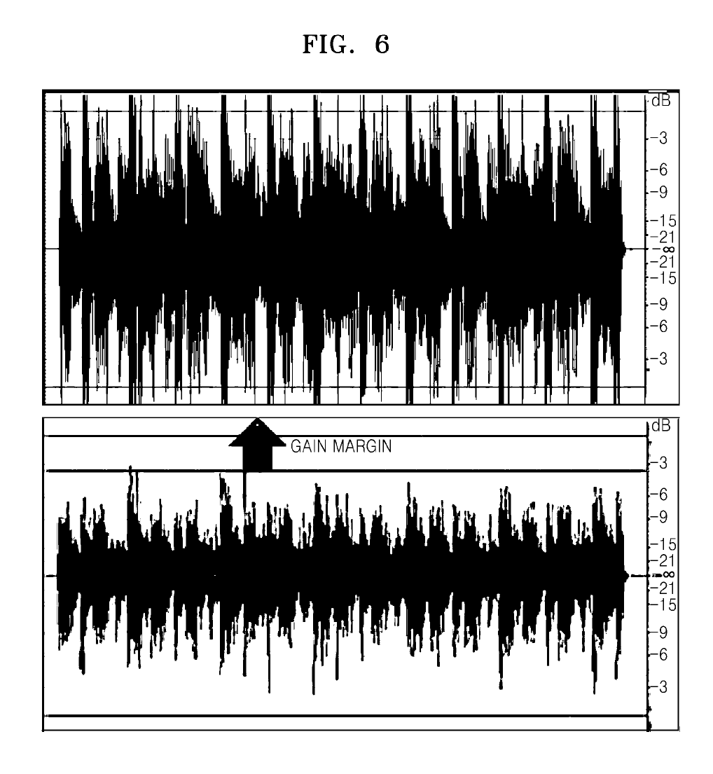

FIG. 6 are graphs illustrating an audio signal, from which the signal of the first frequency band is removed by the volume adjusting apparatus 200, 300, or 450 according to the exemplary embodiments. The graphs of FIG. 6 show the volume of the audio signal in the time domain. The upper graph of FIG. 6 shows the audio signal before the signal of a first frequency band is removed by the volume adjusting apparatus 200, 300, or 450, and the lower graph of FIG. 6 shows the audio signal from which the signal of the first frequency band is removed by the volume adjusting apparatus 200, 300, or 450.

As shown in the lower graph of FIG. 6, when the audio signal from which the audio signal of the first frequency band is removed by the volume adjusting apparatus 200, 300, or 450, is represented in the time domain, the volume of the audio signal is less than that of the original audio signal shown in the upper graph of FIG. 6, and thus, head room for increasing the volume of the audio signal may be secured.

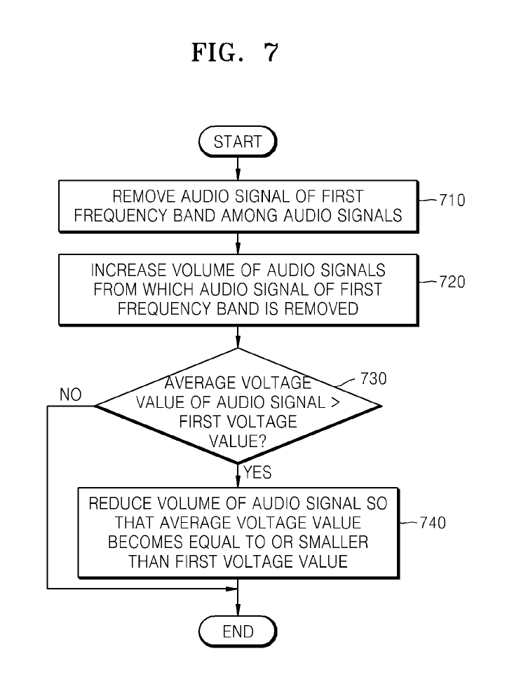

FIG. 7 is a flowchart illustrating a method of processing an audio signal, according to an exemplary embodiment. Referring to FIG. 7, the volume adjusting apparatus 200, 300, or 450 removes the audio signal of the first frequency band among the audio signals (S710). The first frequency band may be included in the frequency band of the audio signal that may not be reproducible through the speaker. For example, the first frequency band may range from about 100 Hz to about 800 Hz. The volume adjusting apparatus 200, 300, or 450 receives the selection of the first frequency band from the user, and removes the audio signal of the selected frequency band.

The volume adjusting apparatus 200, 300, or 450 increases the volume of the audio signals from which the signal of the first frequency band is removed (S720). The volume adjusting apparatus 200, 300, or 450 calculates the amount of reduced volume of the audio signal in the time domain corresponding to the removed signal of the first frequency band. The volume adjusting apparatus 200, 300, or 450 increases the volume of the audio signal by using the calculated amount of the reduced volume.

The volume adjusting apparatus 200, 300, or 450 may reduce the volume of the audio signal to be less than a certain reference value, when the increased volume of the audio signal is excessively large. The volume adjusting apparatus 200, 300, or 450 calculates the average voltage value of the audio signal by the frame unit, and determines whether the average voltage value is greater than the first voltage value (S730). The volume adjusting apparatus 200, 300, or 450 adjusts the volume of the audio signal so that the average voltage value of the audio signal is equal to or less than the first voltage value, with respect to the audio signal having the average voltage value that is greater than the first voltage value in the frame (S740). The volume adjusting apparatus 300 or 450 may reduce the volume of the audio signal of high volume without changing the audio signal having low volume.

The present invention can also be embodied as computer readable code on a computer readable recording medium. The computer readable recording medium is any data storage device that can store data which can be thereafter read by a computer system. Examples of the computer readable recording medium include recording media, such as magnetic storage media (e.g., ROM, floppy disks, hard disks, etc.) and optical recording media (e.g., CD-ROMs, or DVDs), and transmission media such as Internet transmission media. Thus, the medium may be such a defined and measurable structure including or carrying a signal or information, such as a device carrying a bitstream according to one or more embodiments of the present invention. The media may also be a distributed network, so that the computer readable code is stored/transferred and executed in a distributed fashion. Furthermore, the processing element could include a processor or a computer processor, and processing elements may be distributed and/or included in a single device.

According to the exemplary embodiments, the method and apparatus for adjusting volume so that the audio signal may be reproduced to be less than the rated output power of the speaker with a volume of a predetermined standard or greater.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of adjusting volume, the method comprising:
removing a signal of a first frequency band from a first audio signal to output a second audio signal; and
increasing a volume of the second audio signal to output a third audio signal, the second audio signal being the first audio signal not including the first frequency band.

2. The method of claim 1, further comprising generating the first audio signal by recording an input signal,
wherein the generating of the first audio signal comprises adjusting a recording gain so the first audio signal is not saturated.

3. The method of claim 1, wherein the first frequency band is in a frequency band of the first audio signal, that is not reproducible through a speaker.

4. The method of claim 1, wherein a maximum frequency of the first frequency band is equal to or less than 800 Hz.

5. The method of claim 1, further comprising receiving a selection of the first frequency band, from a user.

6. The method of claim 1, wherein the increasing of the volume of the second audio signal comprises:
calculating an amount of volume of the first audio signal that is reduced in a time domain, corresponding to the removed signal of the first frequency band; and
increasing the volume of the second audio signal by using the calculated amount of volume.

7. The method of claim 6, further comprising, when a voltage value of the third audio signal, is greater than a first voltage value, reducing a volume of the third audio signal to output a fourth audio signal so that a voltage value of the fourth audio signal is reduced to be less than the first voltage value.

8. The method of claim 7, wherein the reducing of the volume comprises:
calculating an average voltage value of the third audio signal, in a frame unit; and
reducing the volume of the third audio signal to output the fourth audio signal, so that an average voltage value of the fourth audio signal is less than the first voltage value.

9. The method of claim 7, further comprising:
adjusting a gain of the fourth audio signal; and
outputting the gain-adjusted fourth audio signal.

10. The method of claim 7, wherein the first voltage value is smaller than a value of rated output power of a speaker.

11. The method of claim 10, further comprising increasing the first voltage value so as not to exceed the rated output power of the speaker.

12. The method of claim 11, wherein the increasing of the first voltage value comprises receiving a selection of the first voltage value from a user.

13. A volume adjusting apparatus comprising:
a low frequency signal deduction unit which removes a signal of a first frequency band from a first audio signal to output a second audio signal; and
a volume amplifier which increases volume of the second audio signal to output a third audio signal, the second audio signal not including the first frequency band.

14. The volume adjusting apparatus of claim 13, further comprising an audio signal generator which generates the first audio signal by recording an input signal,
wherein the audio signal generator generates the first audio signal by adjusting a recording gain so the first audio signal is not saturated.

15. The volume adjusting apparatus of claim 13, wherein the first frequency band is in a frequency band of the first audio signal that is not reproducible through a speaker.

16. The volume adjusting apparatus of claim 13, wherein a maximum frequency of the first frequency band is equal to or less than 800 Hz.

17. The volume adjusting apparatus of claim 13, further comprising a user interface for receiving a user's selection of the first frequency band which is removed from the first audio signal.

18. The volume adjusting apparatus of claim 13, wherein the volume amplifier calculates an amount of volume of the first audio signal that is reduced in a time domain corresponding to the removed signal of the first frequency band, and increases the volume of the second audio signal by using the calculated amount of volume.

19. The volume adjusting apparatus of claim 18, further comprising a maximum output adjuster which reduces a volume of the third audio signal to output a fourth audio signal, so that a voltage value of the third audio signal is reduced to be equal to or less than a first voltage value, when the voltage value of the third audio signal is greater than the first voltage value.

20. The volume adjusting apparatus of claim 19, wherein the maximum output adjuster calculates an average voltage value of the third audio signal in a frame unit and reduces the volume of the third audio signal so that the average voltage value of the fourth audio signal is less than the first voltage value.

21. The volume adjusting apparatus of claim 19, further comprising:
an output gain adjuster which adjusts a gain of the fourth audio signal; and
a speaker which outputs the gain-adjusted fourth.

22. The volume adjusting apparatus of claim 19, wherein the first voltage value is equal to or less than a value of rated output power of a speaker.

23. The volume adjusting apparatus of claim 22, wherein the maximum output adjuster increases the first voltage value so that the first voltage value does not exceed the rated output power of the speaker.

24. The volume adjusting apparatus of claim 23, further comprising a user interface which receives a selection of the first frequency band corresponding to the first voltage value.

25. A computer readable recording medium having embodied thereon a program for executing a method of adjusting volume, the method comprising:
removing signal of a first frequency band from a first audio signal to output a second audio signal; and
increasing a volume of the second audio signal, the second audio signal being the first audio signal not including the first frequency band.
